(19) United States
(12) Patent Application Publication
(10) Pub. No.: US 2015/0358004 A1
(43) Pub. Date: Dec. 10, 2015

(54) D-TYPE FLIP-FLOP AND CLOCK GENERATING CIRCUIT

(71) Applicant: Kabushiki Kaisha Toshiba, Tokyo (JP)

(72) Inventors: Toshiaki Shirai, Kawasaki Kanagawa (JP); Hiroaki Muraoka, Kawasaki Kanagawa (JP); Tetsuaki Utsumi, Yokohoma Kanagawa (JP)

(21) Appl. No.: 14/617,732

(22) Filed: Feb. 9, 2015

(30) Foreign Application Priority Data
Jun. 4, 2014 (JP) 2014-116109

(51) Int. Cl. H03K 3/356; H03K 21/00

(52) U.S. Cl. CPC H03K 3/356104; H03K 21/00

(57) ABSTRACT

A D-type flip-flop according to embodiments comprises: a transmission element configured in a slave latch, the transmission element fetching an output of a first latch circuit and outputting the fetched output to a first node, based on a clock signal; a first latch circuit constituting element configured in the first latch circuit, the first latch circuit giving an output of one logical value to the first node through the transmission element with the output fixed in a second mode; and a second latch circuit constituting element configured in the second latch circuit that holds a signal which appears at the first node, the second latch circuit constituting element giving an output of other logical value to the first node based on the clock signal with the output fixed in the second mode.

### CROSS-REFERENCE TO RELATED APPLICATION

This application is based upon and claims the benefit of priority from the prior Japanese Patent Applications No. 2014-116109, filed on Jun. 4, 2014; the entire contents of which are incorporated herein by reference.

### FIELD

Embodiments of the present invention herein relate generally to a D-type flip-flop circuit and a clock generating circuit.

### BACKGROUND

There has been a clock generating circuit capable of outputting clocks having different frequencies. Such a clock generating circuit can provide clocks by selecting the clocks to a module or the like in which processing speed is variable by switching the clocks. In some of such clock generating circuits, a clock frequency dividing circuit having a bypass function is adopted. The clock frequency dividing circuit having the bypass function outputs an output of a clock pulse supply source such as a PLL circuit, as it is, or after dividing a frequency of the output. For example, the clock frequency dividing circuit having the bypass function is configured by a counter that divides a frequency of an output of the PLL circuit and a multiplexer that switches a counter output and a PLL output.

An output of the counter is subjected to synchronization of the edge of cycle time by a D-type flip-flop at the last stage of the counter or a D-type flip-flop arranged immediately after the counter (which is hereinafter referred to as “D-type flip-flop at the last stage”), and then supplied to the multiplexer. That is, a clock latency in a bypass mode in which an output of the PLL circuit is directly outputted through the multiplexer, and a clock latency in a frequency division mode in which the output of the PLL circuit is subjected to frequency division through the counter and then outputted are different from each other by a delay in the D-type flip-flop at the last stage.

Further, in regular digital circuit design, the D-type flip-flop at the last stage and the multiplexer are constituted by standard cells. Therefore, in accordance with physical distances between the respective cells, a clock latency in the frequency division and a latency in the bypass are different from each other. Further, strictly speaking, a delay in the multiplexer slightly varies in dependence on different input pins.

If such clocks having different clock latencies are supplied to the module, there is a case in which timing control is difficult in the module. Besides, it is possible to reduce the latency by arranging standard cells of the D-type flip-flop at the last stage and the multiplexer to be close to each other in a layout, or making the standard cells be one custom cell, but it is not possible to remove a difference in latency caused by a delay in the D-type flip-flop at the last stage.

### BRIEF DESCRIPTION OF THE DRAWINGS

FIG. 1 is a logic circuit diagram showing a D-type flip-flop incorporated into a clock generating circuit according to a first embodiment of the present invention;

FIGS. 2A and 2B are circuit diagrams showing circuits that generate signals to be supplied to respective elements in FIG. 1;

FIG. 3 is a circuit diagram showing a circuit example that specifically realizes the circuits of FIGS. 1, 2A and 2B;

FIG. 4 is a block diagram showing a clock generating circuit according to the present embodiment;

FIG. 5 is a diagram showing a truth table of a D-type flip-flop 1 of the first embodiment;

FIGS. 6A-6D are timing charts showing operations of the clock generating circuit of FIG. 4;

FIG. 7 is a logic circuit diagram showing a general D-type flip-flop;

FIG. 8 is a circuit diagram showing a circuit example that specifically realizes the circuit of FIG. 7;

FIG. 9 is a block diagram showing a clock generating circuit according to related art of the present embodiment;

FIGS. 10A-10D are timing charts showing operations of the clock generating circuit of FIG. 9;

FIG. 11 is a circuit diagram showing a second embodiment of the present invention; and

FIG. 12 is a circuit diagram showing a third embodiment of the present invention.

### DETAILED DESCRIPTION

A D-type flip-flop according to the embodiments is configured by a master latch having a first latch circuit and a slave latch having a second latch circuit, and the D-type flip-flop includes: a transmission element configured in the slave latch, the transmission element fetching an output of the first latch circuit based on a clock signal and outputting the fetched output to a first node; a first latch circuit constituting element configured in the first latch circuit, the first latch circuit constituting element functioning as an element that constitutes the first latch circuit in a first mode and outputting an output for giving one logical value to the first node through the transmission element with the output fixed in a second mode, under control of a control signal; and a second latch circuit constituting element configured in the second latch circuit that holds a signal which appears at the first node, the second latch circuit constituting element functioning as an element that constitutes the second latch circuit in the first mode and outputting an output of other logical value to the first node based on the clock signal with the output fixed in the second mode, under control of the control signal.

Hereinafter, embodiments of the present invention will be described in detail referring to the drawing.

### First Embodiment

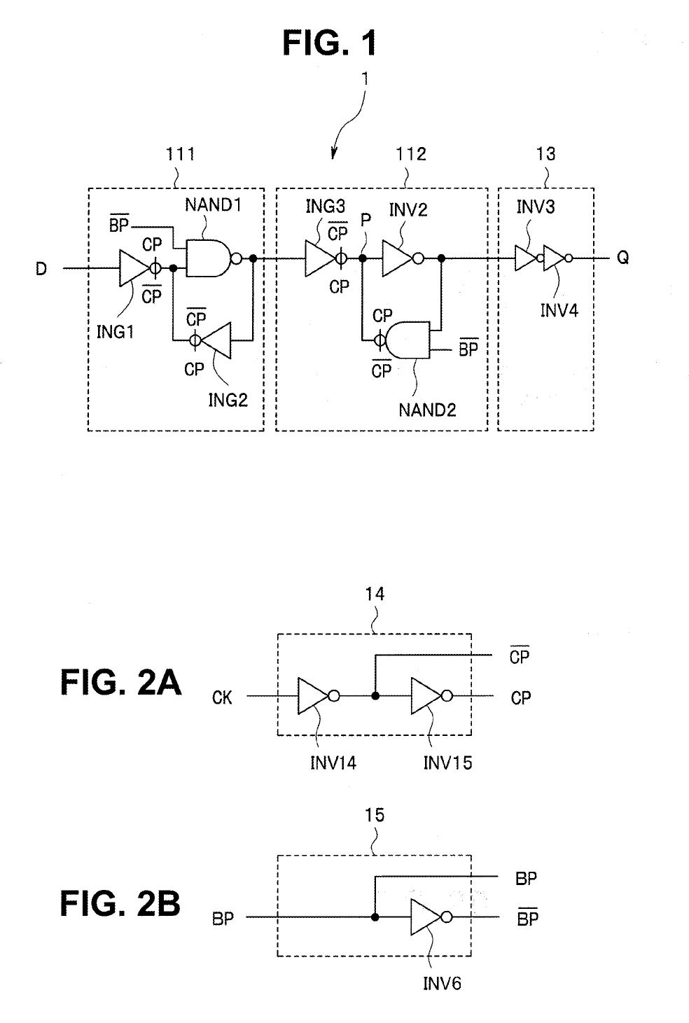

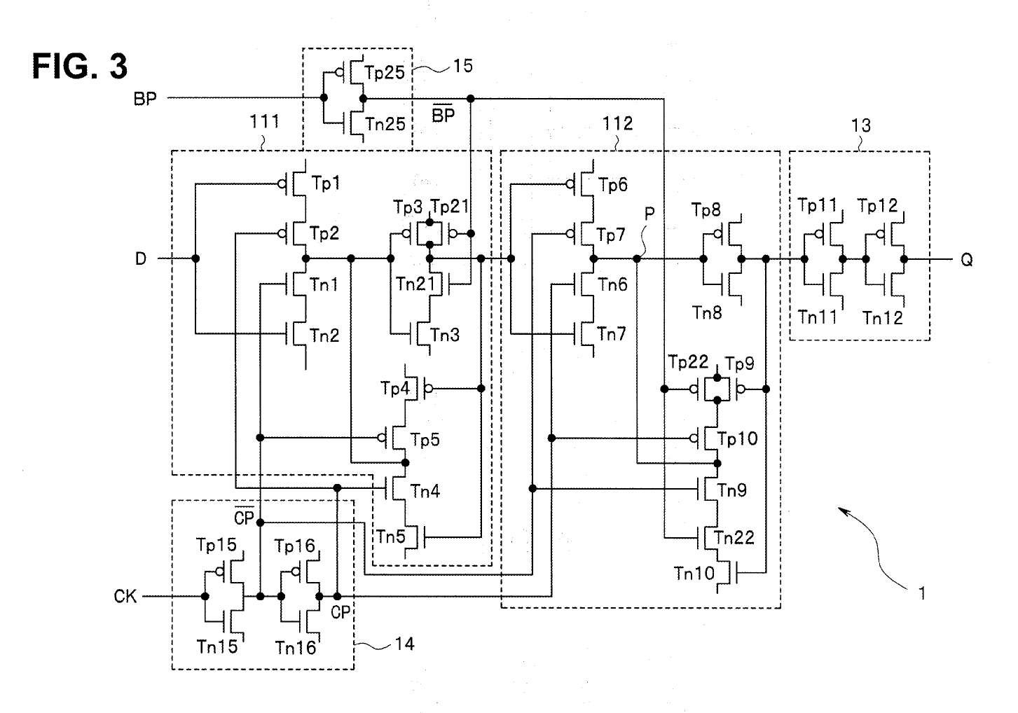

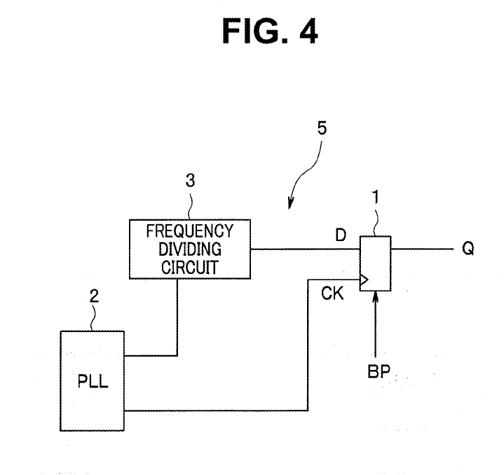

FIG. 1 is a logic circuit diagram showing a D-type flip-flop incorporated into a clock generating circuit according to a first embodiment of the present invention. FIGS. 2A and 2B are circuit diagrams showing circuits that generate signals to be supplied to respective elements in FIG. 1. Further, FIG. 3 is a circuit diagram showing a circuit example that specifically realizes the circuits of FIGS. 1, 2A and 2B. FIG. 4 is a block diagram showing a clock generating circuit according to the present embodiment. It is noted that circuit parts denoted by reference signs 111, 112 and 13-15 in FIGS. 1 through 3 are shown as the same circuit parts by the same reference signs. Further, in FIG. 3, connections to a power supply line are omitted for the sake of simplification of the drawings.

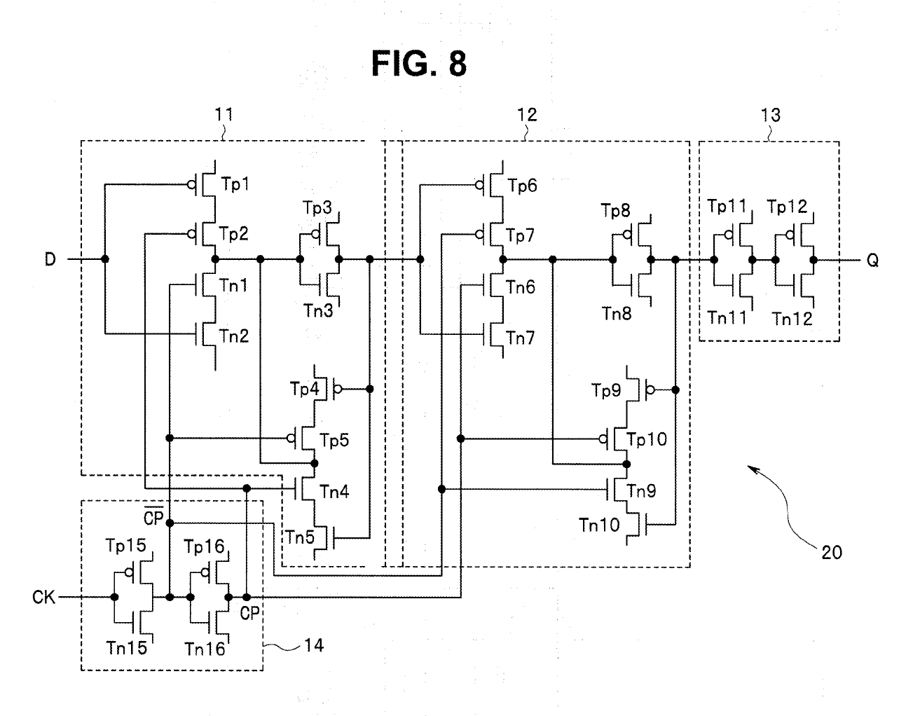

First, in order to make it easy to understand features in the first embodiment, a general D-type flip-flop which is related art of the present embodiment will be described referring to FIGS. 7 and 8. It is noted that, in the description regarding FIGS. 1 through 3 as given later, the same reference signs are assigned to the same elements in FIGS. 7 and 8 and the description thereof is omitted.

FIG. 7 is a logic circuit diagram showing a general D-type flip-flop, and FIG. 8 is a circuit diagram showing a circuit example that specifically realizes the circuit of FIG. 7. It is noted that, circuit parts denoted by reference signs 11-13 in FIGS. 7 and 8 are shown as the same circuit parts by the same reference signs. It is noted that, in FIG. 8, connections to a power supply line are omitted for the sake of simplification of the drawings.

In FIG. 7, a data input D supplied to a D-type flip-flop 20 is given to an inverter ING1 which is a clocked inverter in a master latch 11. The inverter ING1 fetches the data input D into the master latch 11 under control of a clock CP and an inverted clock CP bar (hereinafter referred to as “/CP”) which are supplied to a control terminal. For example, the inverter ING1 fetches the data input D and supplies the data input D to an inverter INV1 when the clock CP is in low level (hereinafter referred to as “L level”).

The inverter INV1 inverts an input signal and gives the inverted signal to an inverter ING2 which is a clocked inverter. The inverter ING2 inverts an input signal and gives the inverted signal to the inverter INV1 under control of the inverted clock /CP and the clock CP which are inputted to a control terminal. For example, the inverter ING2 fetches an output of the inverter INV1 and outputs the fetched output to the inverter INV1 when the clock CP is in high level (hereinafter referred to as “H level”). That is, the inverters INV1 and ING2 function as a latch circuit, and output and hold a non-inverting signal of the data input D during an H level period of the clock CP.

The output of the inverter INV1 is supplied to an inverter ING3 which is a clocked inverter as a transmission element. The inverter ING3 fetches the output of the inverter INV1 into a slave latch 12 under control of the inverted clock /CP and the clock CP which are inputted to a control terminal. For example, the inverter ING3 fetches the output of the inverter INV1 and supplies the fetched output to an inverter INV2 when the clock CP is in H level.

The inverter INV2 inverts an input signal and gives the inverted signal to an inverter ING4 which is a clocked inverter. The inverter ING4 inverts an input signal and gives the inverted signal to the inverter INV2 under control of the clock CP and the inverted clock /CP which are inputted to a control terminal. For example, the inverter ING4 fetches an output of the inverter INV2 and makes an output to the inverter INV2 when the clock CP is in L level. That is, the inverters INV2 and ING4 function as a latch circuit, and output the non-inverting signal of the data input D to a buffer circuit 13 and hold the non-inverting signal during an L level period of the clock CP.

Inverters INV3 and INV4, which constitute the buffer circuit 13, output an inputted signal as a data output Q. Thus, the signal data propagated from an input D terminal is outputted as the data through an output Q terminal in synchronism with the clock CP.

In FIG. 8, a source-drain path of a PMOS transistor Tp1, a source-drain path of a PMOS transistor Tp2, a drain-source path of an NMOS transistor Tn1 and a drain-source path of an NMOS transistor Tn2 are connected in series between a power supply terminal and a reference potential point, and the inverter ING1 in FIG. 7 is constituted by these transistors Tp1, Tp2, Tn1 and Tn2. The data input D is supplied to gates of the transistors Tp1 and Tn2, and the clock CP and the inverted clock /CP are supplied to a gate of the transistor Tp2 and a gate of the transistor Tn1, respectively, from a control clock generating section 14.

To the control clock generating section 14, a clock CK is supplied from a PLL circuit which is described later. The control clock generating section 14 is constituted by an inverter by transistors Tp15 and Tn15, and an inverter by transistors Tp16 and Tn16. Between the power supply terminal and the reference potential point, a source-drain path of the PMOS transistor Tp15 and a drain-source path of the NMOS transistor Tn15 are connected in series, and a source-drain path of the PMOS transistor Tp16 and a drain-source path of the NMOS transistor Tn16 are connected in series. The clock CK is supplied to gates of the transistors Tp15 and Tn15, and the inverter by the transistors Tp15 and Tn15 inverts the clock CK and outputs the inverted clock /CP. The inverted clock /CP is supplied to gates of the transistors Tp16 and Tn16, and the inverter by the transistors Tp16 and Tn16 inverts the inverted clock /CP and outputs the clock CP.

The transistor Tp2 turns on when the clock CP is in L level and turns off when the clock CP is H level. Further, the transistor Tn1 turns on when the inverted clock /CP is in H level and turns off when the inverted clock /CP is L level. Therefore, the inverter ING1 by the transistors Tp1, Tp2, Tn1 and Tn2 inverts the data input D and outputs the inverted data input from a common drain of the transistors Tp2 and Tn1 only in the L level period of the clock CP.

The transistors Tp3 and Tn3 correspond to the inverter INV1 in FIG. 7. A source-drain path of the PMOS transistor Tp3 and a drain-source path of the NMOS transistor Tn3 are connected directly between the power supply terminal and the reference potential point, and an output of the common drain of the transistors Tp2 and Tn1 is given to gates of the transistors Tp3 and Tn3. The transistors Tp3 and Tn3 invert a signal inputted to the gates and supply the inverted signal to gates of transistors Tp4 and Tn5.

A source-drain path of the PMOS transistor Tp4, a source-drain path of a PMOS transistor Tp5, a drain-source path of an NMOS transistor Tn4, and a drain-source path of the NMOS transistor Tn5 are connected in series between the power supply terminal and the reference potential point, and the transistors Tp4, Tp5, Tn4 and Tn5 constitute the inverter ING2 in FIG. 7. The inverted clock /CP is supplied to a gate of the transistor Tp5, the clock CP is supplied to a gate of the transistor Tn4, and the transistor Tp5 turns on when the inverted clock /CP is in L level and turns off when the inverted clock /CP is in H level. Further, the transistor Tn4 turns on when the clock CP is in H level and turns off when the clock CP is in L level. Therefore, the inverter ING2 by the transistors Tp4, Tp5, Tn4 and Tn5 inverts an output of a common drain of the transistors Tp3 and Tn3 and outputs the inverted output to the gates of the transistors Tp3 and Tn3 only in the H level period of the clock CP.

Transistors Tp6, Tp7, Tn6 and Tn7 in the slave latch 12 constitute the inverter ING3 in FIG. 7. A source-drain path of the PMOS transistor Tp6, a source-drain path of the PMOS transistor Tp7, a drain-source path of the NMOS transistor Tn6, and a drain-source path of the NMOS transistor Tn7 are connected in series between the power supply terminal and the reference potential point, and the output of the common drain of the transistors Tp3 and Tn3 is supplied to gates of the transistors Tp6 and Tn7.

The inverted clock /CP is supplied to a gate of the transistor Tp7 and the clock CP is supplied to a gate of the transistor Tn6, and the transistor Tp7 turns on when the inverted clock /CP is in L level and turns off when the inverted clock /CP is in H level. Further, the transistor Tn6 turns on when the clock CP is in H level and turns off when the clock CP is in L level. Therefore, the inverter ING3 by the transistors Tp6, Tp7, Tn6 and Tn7 inverts the output of the common drain of the transistors Tp3 and Tn3 and outputs the inverted output to gates of transistors Tp8 and Tn8 only in the H level period of the clock CP.

The transistors Tp8 and Tn8 correspond to the inverter INV2 in FIG. 7. A source-drain path of the PMOS transistor Tp8 and a drain-source path of the NMOS transistor Tn8 are connected directly between the power supply terminal and the reference potential point, and an output of a common drain of the transistors Tp7 and Tn6 is given to gates of the transistors Tp8 and Tn8. The transistors Tp8 and Tn8 invert a signal inputted to the gates and supply the inverted signal to gates of transistors Tp9 and Tn10.

A source-drain path of the PMOS transistor Tp9, a source-drain path of a PMOS transistor Tp10, a drain-source path of an NMOS transistor Tn9 and a drain-source path of the NMOS transistor Tn10 are connected in series between the power supply terminal and the reference potential point, and the transistors Tp9, Tp10, Tn9 and Tn10 constitute the inverter ING4 in FIG. 7. The clock CP is supplied to a gate of the transistor Tp10 and the inverted clock /CP is supplied to a gate of the transistor Tn9, and the transistor Tp10 turns on when the clock CP is in L level and turns off when the clock CP is in H level. Further, the transistor Tn9 turns on when the inverted clock /CP is in H level and turns off when the inverted clock /CP is in L level. Therefore, the inverter ING4 by the transistors Tp9, Tp10, Tn9 and Tn10 inverts an output of a common drain of the transistors Tp8 and Tn8 and outputs the inverted output to the gates of the transistors Tp8 and Tn8 only in an H level period of the inverted clock /CP.

The output of the common drain of the transistors Tp8 and Tn8 is supplied to gates of transistors Tp11 and Tn11 which constitute the buffer circuit 13. The buffer circuit 13 is constituted by the inverter INV3 by the transistors Tp11 and Tn11, and the inverter INV4 by transistors Tp12 and Tn12. A source-drain path of the PMOS transistor Tp11 and a drain-source path of the NMOS transistor Tn11 are connected in series between the power supply terminal and the reference potential point, and a source-drain path of the PMOS transistor Tp12 and a drain-source path of the NMOS transistor Tn12 are connected in series between the power supply terminal and the reference potential point. The transistors Tp11 and Tn11 invert a signal supplied to the gates and output the inverted signal to gates of the transistors Tp12 and Tn12. The transistors Tp12 and Tn12 invert a signal supplied to the gates and output the inverted signal as the data output Q.

As described above, the master latch 11, the slave latch 12 and the buffer circuit 13 operate in the same manner as in FIG. 7, and output the data input D to be synchronized with the clock CP, as the data output Q.

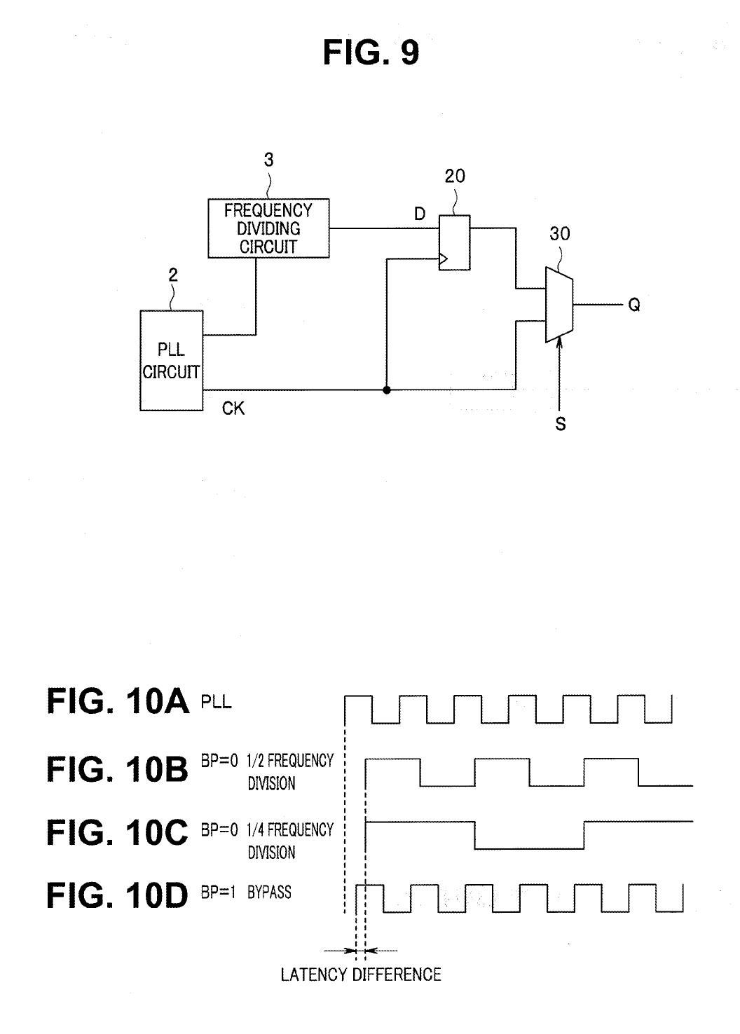

FIG. 9 is a block diagram showing a clock generating circuit according to related art of the present embodiment, which is configured using the D-type flip-flop 20 shown in FIGS. 7 and 8. Further, FIGS. 10A-10D are timing charts showing operations of the clock generating circuit of FIG. 9.

The PLL (phase-locked loop) circuit 2 generates the clock CK having a predetermined frequency as shown in FIG. 10A and outputs the clock to a frequency dividing circuit 3 and a multiplexer 30. The frequency dividing circuit 3 performs frequency division of an output of the PLL circuit 2 and gives a frequency division output to the D-type flip-flop 20 as the data input D. Besides, it is described that the D-type flip-flop 20 is arranged at a subsequent stage of the frequency dividing circuit 3, but the D-type flip-flop 20 may be a D-type flip-flop at the last stage of the frequency dividing circuit 3.

The D-type flip-flop 20 outputs the data input D to the multiplexer 30 as the data output Q at timing in synchronism with the clock CP generated based on the clock CK from the PLL circuit 2. The multiplexer 30 selects an output of the PLL circuit 2 in a bypass mode and selects an output of the D-type flip-flop 20 in a frequency division mode under control of a control signal S, and outputs the selected output as the data output Q. For example, the control signal S is in H level in the bypass mode and in L level in the frequency division mode. The multiplexer 30 selects the output of the D-type flip-flop 20 when the control signal S is in L level (logical value “0”) and outputs the selected output as the data output Q, and selects the output of the PLL circuit 2 when the control signal S is in H level (logical value “1”) and outputs the selected output as the data output Q.

FIG. 10B shows the data output Q in a case of ½ frequency division and FIG. 10C shows the data output Q in a case of ¼ frequency division. These data outputs Q delay in comparison with the clock CK from the PLL circuit 2 due to delays in the respective transistors shown in FIG. 8.

Further, FIG. 10D shows the output when the control signal S is in H level, i.e. the output in the bypass mode, in which the clock CK from the PLL circuit 2 is outputted from the multiplexer 30 with the frequency without change. Thus, the clocks of the output of the PLL circuit 2 and the output of the frequency dividing circuit, which have different frequencies, are outputted.

However, in the clock generating circuit of FIG. 9, a route in which the clock CK from the PLL circuit 2 transmits in the frequency dividing mode is different from a route in which the clock CK from the PLL circuit 2 transmits in the bypass mode, and clock latencies are different by a delay in the D-type flip-flop 20 at the last stage, as shown in FIGS. 10A-10D.

On the other hand, a clock generating circuit 5 of FIG. 4 according to the present embodiment differs from the clock generating circuit of FIG. 9, which is the related art, in that a D-type flip-flop 1 as shown in FIGS. 1 to 3 is adopted in place of the D-type flip-flop 20 and the multiplexer 30. The D-type flip-flop 1 at the last stage is capable of operating in a frequency division mode and a bypass mode, and causing clock latencies in the frequency division mode and in the bypass mode to coincide with each other. It is noted that the frequency division mode in the D-type flip-flop 1 means a mode in which a regular D-type flip-flop operation is performed, i.e. a non-bypass mode, and the bypass mode in the D-type flip-flop 1 means a mode in which an inputted clock is outputted as it is with the same logic.

As shown in FIG. 1, the D-type flip-flop 1 differs from the D-type flip-flop 20 of FIG. 7 in that a NAND circuit NAND1 is adopted in a master latch 111 in place of the inverter INV1 in FIG. 7, and a clocked NAND circuit NAND2 is adopted in a slave latch 112 in place of the inverter ING4 in FIG. 7.

FIGS. 2A and 2B show circuits that generates signals to be supplied to respective elements in FIG. 1, FIG. 2A shows the control clock generating section 14, and FIG. 2B shows a control signal generating section 15 that generates an inverted control signal BP bar (hereinafter referred to as “inverted control signal /BP”).

The control clock generating section 14 is constituted by two stages of inverters INV14 and INV15. The inverter INV14 inverts the inputted clock CK and outputs the inverted clock /CP, and the inverter INV15 inverts an output of the inverter INV14 and outputs the non-inverting clock CP. Therefore, the clock CP is generated in synchronism with the clock CK.

The control signal generating section 15 is constituted by an inverter INV6. The inverter INV6 inverts an inputted control signal BP and outputs the inverted control signal /BP. It is noted that the control signal BP is a signal which is in H level in the bypass mode and is in L level in the frequency dividing mode (non-bypass mode). That is, the control signal BP is a signal similar to the signal that controls the multiplexer 30 in FIG. 9, and is generated by a control circuit, not shown, which controls switching of frequencies of output clocks.

In FIG. 1, an output of the inverter ING1 is given to one input terminal of the NAND circuit NAND1 and the inverted control signal /BP is given to the other input terminal of the NAND circuit NAND1. The NAND circuit NAND1 functions as an inverter that inverts an input signal and outputs the inverted signal when the control signal BP is in L level and the inverted control signal /BP is in H level. Further, the NAND circuit NAND1 outputs an output in H level irrespective of the input signal when the inverted control signal /BP is in L level.

Further, an output of the inverter INV2 is given to one input terminal of the clocked NAND circuit NAND2 and the inverted control signal /BP is given to the other input terminal of the clocked NAND circuit NAND2. The clocked NAND circuit NAND2 functions as a clocked inverter that inverts an input signal and outputs the inverted input signal based on the clock CP and the inverted clock /CP. Further, the clocked NAND circuit NAND2 outputs an output in H level irrespective of the input signal when the inverted control signal /BP is in L level.

Therefore, when the inverted control signal /BP is in H level, i.e. in the non-bypass mode, the D-type flip-flop 1 of FIG. 1 has the same configuration as that of the D-type flip-flop 20 in FIG. 7 and outputs the data input D as the data output Q at timing of the clock CP.

On the other hand, when the inverted control signal /BP is in L level, i.e. in the bypass mode, the output of the NAND circuit NAND1 is fixed to be in H level. In this case, a level of a node P which is an input terminal of the inverter INV2 depends on outputs of the inverter ING3 and the clocked NAND circuit NAND2.

The inverter ING3 inverts the input in H level to cause the node P to be in L level when the clock CP is in H level and the inverted clock /CP is in L level. It is noted that the inverter ING3 does not contribute transition of the node P when the clock CP is in L level and the inverted clock /CP is in H level.

On the other hand, the clocked NAND circuit NAND2 causes the node P to be in H level irrespective of the output of the inverter INV2 when the clock CP is in L level and the inverted clock /CP is in H level. It is noted that the clocked NAND circuit NAND2 does not contribute transition of the node P when the clock CP is in H level and the inverted clock /CP is in L level.

That is, in the case where the inverted control signal /BP is in L level, the node P is in L level when the clock CP is in H level, and the node P is in H level when the clock CP is in L level. The level of the node P is inverted by the inverter INV2 and outputted as the data output Q through the buffer circuit 13. That is, in the case where the inverted control signal /BP is in L level, the clock CP is outputted, as it is, with the same logic as the data output Q, and the configuration is equivalent to a configuration that the clock CK, which is the output of the PLL circuit 2, is outputted in a bypassing manner.

A description will be made further in detail referring to FIG. 3. In FIG. 3, the inverter INV6 in FIG. 2B is configured by transistors Tp25 and Tn25 which constitute the control signal generating section 15. A source-drain path of the PMOS transistor Tp25 and a drain-source path of the NMOS transistor Tn25 are connected in series between the power supply terminal and the reference potential point, and the control signal BP is applied to gates of the transistors Tp25 and Tn25. An inverter by the transistors Tp25 and Tn25 inverts the inputted control signal BP and outputs the inverted control signal /BP.

The inverted control signal /BP is supplied to gates of transistors Tp21 and Tn21. The NAND circuit NAND1 in FIG. 1 is configured by transistors Tp3, Tn3, Tp21 and Tn21. A source and a drain of the PMOS transistor Tp21 are connected to a source and a drain of the transistor Tp3, respectively. A source-drain path of the NMOS Tn21 is connected between the drain of the transistor Tp3 and a drain of the transistor Tn3. When the inverted control signal /BP is in H level, i.e. in the non-bypass mode, the transistor Tp21 is off and the transistor Tn21 is on. That is, in this case, the transistors Tp3, Tn3, Tp21 and Tn21 function as an inverter by the transistors Tp3 and Tn3 in the same manner in FIG. 8.

On the other hand, when the inverted control signal /BP is in L level, i.e. in the bypass mode, the transistor Tp21 is on and the transistor Tn21 is off. Therefore, in this case, the drain of the transistor Tp21 and a drain of the transistor Tn21 are always in H level.

The clocked NAND circuit NAND2 in FIG. 1 is configured by transistors Tp9, Tp10, Tn9, Tn10, Tp22 and Tn22. A source and a drain of the PMOS transistor Tp22 are connected to a source and a drain of the transistor Tp9, respectively. A source-drain path of the NMOS transistor Tn22 is connected between a source of the transistor Tn9 and a drain of the transistor Tn10. The inverted control signal /BP is supplied to gates of the transistors Tp22 and Tn22.

When the inverted control signal /BP is in H level (in the non-bypass mode), the transistor Tp22 is off and the transistor Tn22 is on. That is, in this case, the transistors Tp9, Tp10, Tn9, Tn10, Tp22 and Tn22 function as a clocked inverter by the transistors Tp9, Tp10, Tn9 and Tn10 in the same manner as in FIG. 8.

On the other hand, when the inverted control signal /BP is in L level, i.e. in the bypass mode, the transistor Tp22 is on and the transistor Tn22 is off. Therefore, whether or not a level of drains of the transistor Tp10 and the transistor Tn9, which are connected to the node P, changes to be in H level is determined in dependence on an on/off state of the transistor Tp10, irrespective of the level of drains of the transistors Tp8 and Tn8 which constitute the inverter INV2.

Further, when the inverted control signal /BP is in L level, the drain of the transistor Tp21 is always in H level, and therefore the transistor Tp6 is off and the transistor Tn7 is on in the inverter ING3 constituted by the transistors Tp6, Tp7, Tn6 and Tn7. Therefore, whether or not a level of drains of the transistor Tp7 and the transistor Tn6, which are connected to the node P, changes to the L level is determined in dependence on an on/off state of the transistor Tn6.

When the clock CP is in H level and the inverted clock /CP is in L level, the transistor Tn6 is on and the transistor Tp10 is off. Therefore, in this case, the node P is in L level. Contrary, when the clock CP is in L level and the inverted clock /CP is in H level, the transistor Tn6 is off and the transistor Tp10 is on. Therefore, in this case, the node P is in H level.

The level of the node P is inverted by the inverter of the transistors Tp8 and Tn8 and outputted through the buffer circuit 13 as the data output Q. That is, when the clock CP is in H level, the data output Q is also in H level, and when the clock CP is in L level, the data output Q is also in L level. Thus, the data output Q has the same logic as the clock CP irrespective of the data input D, the bypass mode in which the clock CK is outputted as it is with the same logic, as the data output Q is realized.

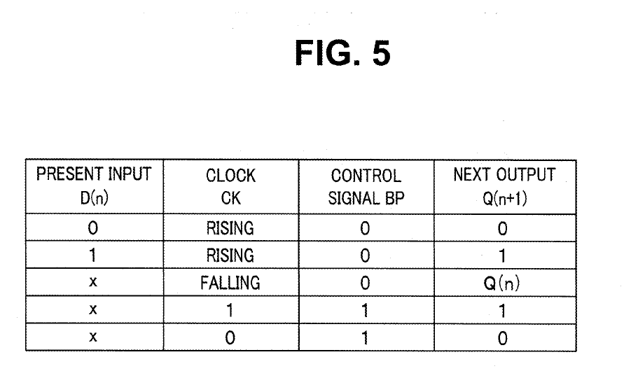

FIG. 5 is a diagram showing a truth table of the D-type flip-flop 1 of the first embodiment. It is noted that “x” indicates that a value “0” or “1” is allowable. In the case where the control signal BP has a logical value “0”, the present data input D(n) is outputted as the next data output Q(n+1) in synchronism with rising of the next clock CK.

Further, in the case where the control signal BP has a logical value “1”, the logical value “1” is outputted when the clock CK has the logical value “1” and the logical value “0” is outputted when the clock CK has the logical value “0”, irrespective of the present input. That is, this case is equivalent to a case where the clock CK is transmitted and outputted as it is.

Next, latencies in the frequency dividing mode (non-bypass mode) and in the bypass mode will be described.

The clock held by the master latch 111 is outputted through the slave latch 112. Therefore, the clock latency is determined by timing of the data output Q of the slave latch 112. That is, a delay by the respective transistors through which the change of the clock at the input terminal is transmitted to the output terminal of the data output Q influences the clock latency.

When the clock rises from the L level to the H level, the clock CP transmits through the transistors Tn15 and Tp16 and is applied to the gate of the transistor Tn6 which constitutes the inverter ING3 in the slave latch 112. The delay by the transistors Tn15 and Tp16 is the same in the frequency division mode and in the bypass mode.

A falling delay in an inverter operation (in the non-bypass mode) of the inverter ING3 is determined by the transistor Tn6 which operates according to the clock CP. Further, in the bypass mode, the transition to the H level of the node P is determined by the transistor Tn6 when the clock CP rises, and thus delay mounts to the node P are the same in the frequency division mode and in the bypass mode. The transmission path of the clock from the node P to the output terminal of the data output Q is the same in the frequency division mode and in the bypass mode, and latencies in rising of the clock CP are the same in the frequency division mode and in the bypass mode.

Further, it is assumed that the clock falls from the H level to the L level. In this case, the delay mount to the node P in the frequency division mode is determined by the transistor Tn6 of the inverter ING3 which operates according to the clock CP, but in contrast, the delay mount to the node P in the bypass mode is determined by the transistor Tp10 in the clocked NAND circuit NAND2 which operates according to the clock CP.

Therefore, a slight difference is made in latency in the frequency division mode and in the bypass mode when the clock CP falls from the H level to the L level. However, a difference between a transition time of the transistor Tp10 and a transition time of the transistor Tn6 is little to have an extremely small value in comparison with the latency difference in the related art of FIG. 8 and there is no problem in practice if it is used as having no latency difference. Further, in the modules that use data outputs Q having different frequencies, there are many modules that perform timing control using a rising edge of the clock, and there arises no problem in the timing control in the modules that use the data outputs Q having different frequencies if the latencies in the frequency division mode and in the bypass mode are the same in rising of the clock CP.

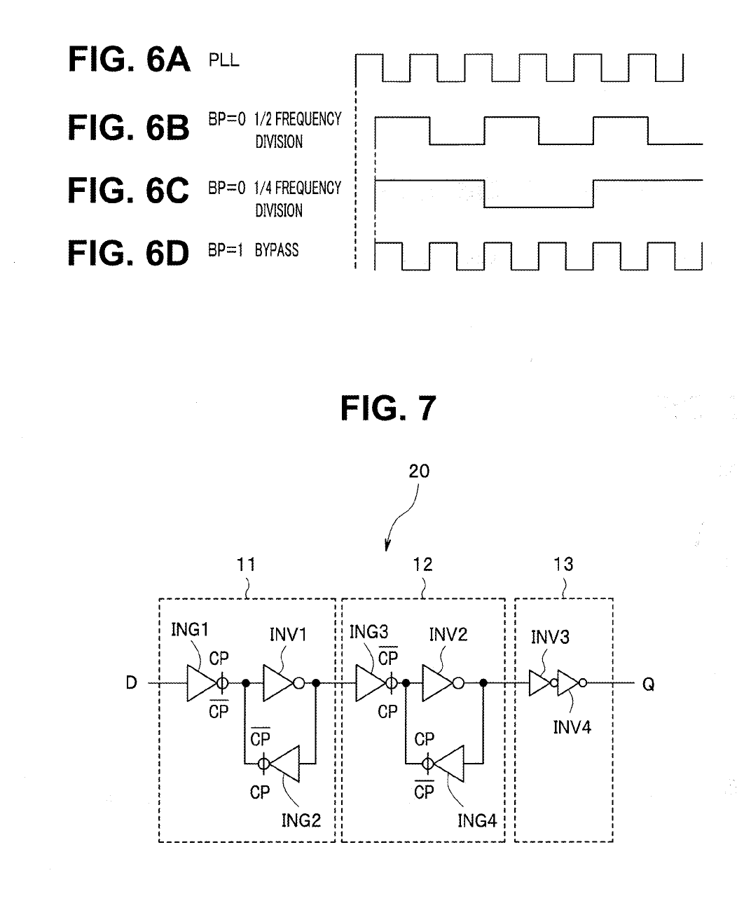

FIGS. 6A-6D are timing charts showing operations of the clock generating circuit of FIG. 4.

In FIG. 4, the PLL circuit 2 generates the clock CK having a predetermined frequency as shown in FIG. 6A and outputs the clock to the frequency dividing circuit 3 and the D-type flip-flop 1. The frequency dividing circuit 3 performs frequency division of an output of the PLL circuit 2 and gives a frequency division output to the D-type flip-flop 1 as the data input D. Besides, it is described that the D-type flip-flop 1 is arranged at a subsequent stage of the frequency dividing circuit 3, but the D-type flip-flop 1 may be a D-type flip-flop at the last stage of the frequency dividing circuit 3.

The D-type flip-flop 1 outputs the data input D as the data output Q when the control signal BP is in L level (logical value “0”), i.e. in the frequency division mode (non-bypass mode) at timing in synchronism with the clock CP generated based on the clock CK from the PLL circuit 2.

FIG. 6B shows the data output Q in a case of ½ frequency division and FIG. 6C shows the data output Q in a case of ¼ frequency division. These data outputs Q delay with respect to the clock CK from the PLL circuit 2 due to delays of the respective transistors shown in FIG. 3.

On the other hand, when the control signal BP is in H level (logical value “I”), i.e. in the bypass mode, the D-type flip-flop 1 outputs the data output Q having the same logic as the clock CK from the PLL circuit 2 irrespective of the data input D, at timing in synchronism with the clock CP generated based on the clock CK. FIG. 6D shows this bypass output and, as mentioned above, the difference of latencies in the non-bypass mode and in the bypass mode is zero or of a sufficiently small value.

As described, in the present embodiment, the NAND circuit is adopted in place of the inverter which constitutes the latch circuit of the master latch, the clocked NAND circuit is adopted in place of the clocked inverter which constitutes the latch circuit of the slave latch, and the control signal for controlling whether the bypass mode is to be set or not is supplied to one input terminal of each of these NAND circuits, to thereby enable the operations in the bypass mode and in the frequency dividing mode. In this case, the transmission paths of the clocks in the bypass mode and in the frequency dividing mode are equal to each other or approximately equal to each other, and it is possible to make the latency difference in the respective modes be zero or of an extremely small value.

It is noted that the tri-state D-type flip-flop is described as an example in the present embodiment, but it is not limited to the tri-state type.

### Second Embodiment

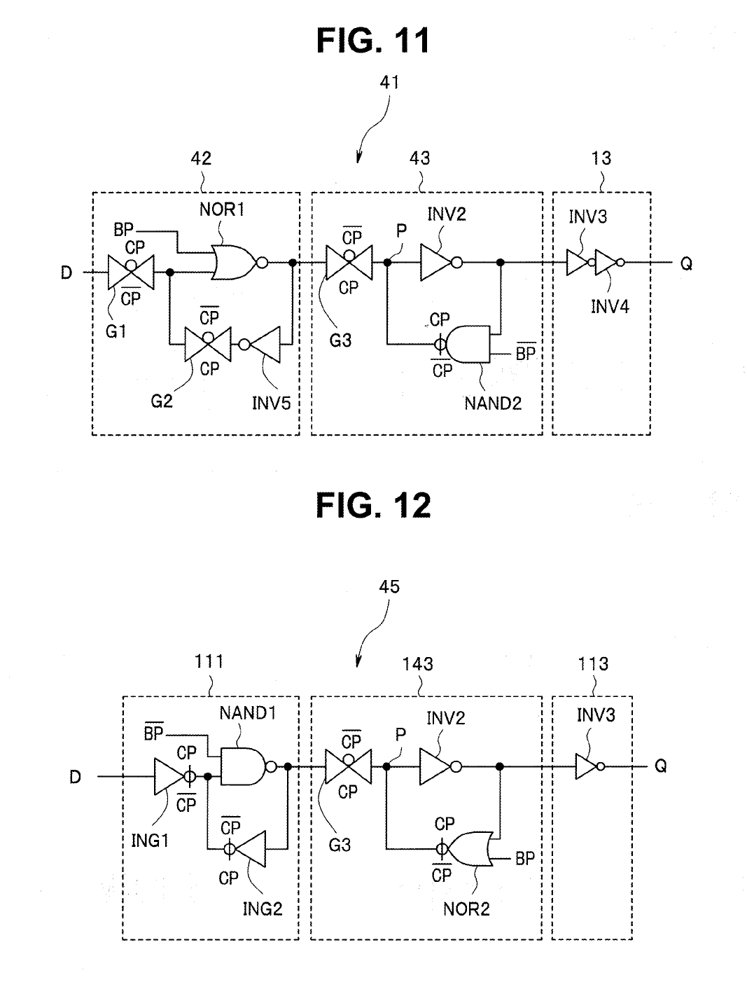

FIG. 11 is a circuit diagram showing a second embodiment of the present invention. In FIG. 11, the same reference signs are assigned to the same elements in FIG. 1 and the description thereof is omitted. An example of the tri-state D-type flip-flop is shown in the first embodiment, but the present embodiment shows an example of a transmission-gate D-type flip-flop.

A D-type flip-flop 41 in the present embodiment differs from the D-type flip-flop 1 in FIG. 1 in that transmission gates G1 and G3 are adopted in place of the inverters ING1 and ING3, an inverter INV5 and a transmission gate G2 are adopted in place of the inverter ING2, and a NOR circuit NOR1 is adopted in place of the NAND circuit NAND1.

In FIG. 11, the data input D supplied to the D-type flip-flop 41 is given to the transmission gate G1 in a master latch 42. The transmission gate G1 fetches the data input D into the master latch 42 and gives the data input to one input terminal of the NOR circuit NOR1 under control of the clock CP and the inverted clock /CP thereof which are supplied to a control end. For example, the transmission gate G1 outputs the inputted signal in L level of the clock CP. The control signal BP is supplied to the other input terminal of the NOR circuit NOR1.

An output of the NOR circuit NOR1 is supplied to the inverter INV5. The inverter INV5 inverts the output of the NOR circuit NOR1 and outputs the inverted output to the transmission gate G2. The transmission gate G2 outputs the inputted signal to the one input terminal of the NOR circuit NOR1 under control of the inverted clock /CP and the clock CP which are supplied to a control terminal. That is, a latch circuit is configured by the NOR circuit NOR1, the inverter INV5 and the transmission gate G2, and the latch circuit outputs and holds an inverted signal of the data input D in the H level period of the clock CP.

The output of the NOR circuit NOR1 is supplied to the transmission gate G3 as a transmission element. The transmission gate G3 fetches an output of the NOR circuit NOR1 into a slave latch 43 under control of the inverted clock /CP and the clock CP which are inputted to a control terminal. For example, the transmission gate G3 outputs the inputted signal in H level of the clock CP.

The inverter INV2 inverts the input signal and gives the inverted input signal to one input terminal of the clocked NAND circuit NAND2. The inverted control signal /BP is given to the other input terminal of the clocked NAND circuit NAND2. The clocked NAND circuit NAND2 gives the inputted signal to the inverter INV2 under control of the clock CP and the inverted clock /CP which are supplied to a control terminal. That is, the inverter INV2 and the clocked NAND circuit NAND2 functions as a latch circuit which outputs the non-inverting signal of the data input D to the buffer circuit 13 and holds the signal in the L level period of the clock CP. The buffer circuit 13 outputs an output of the inverter INV2 as the data output Q.

The other configurations are the same as those of the first embodiment.

Next, an operation of the thus configured embodiment will be described.

When the control signal BP is in L level and the inverted control signal /BP is in H level, i.e. in the frequency division mode (non-bypass mode), the NOR circuit NOR1 functions as an inverter and the clocked NAND circuit NAND2 functions as a clocked inverter. Therefore, in this case, the NOR circuit NOR1 exhibits the same operation as the inverter INV1 in FIG. 7. Further, the inverter INV5 and the transmission gate G2 exhibit the same operation as the inverter ING2 in FIG. 7.

Therefore, when the control signal BP is in L level, the latch circuit in the master latch 42 outputs and holds the inverted signal of the data input D, and the latch circuit in the slave latch 43 inverts the output of the master latch 42 and holds the inverted output. That is, the latch circuit in the slave latch 43 outputs the non-inverting signal of the data input D to the buffer circuit 13 and holds the non-inverting signal. In this case, the D-type flip-flop 41 in FIG. 11 performs an operation of an ordinary D-type flip-flop.

In the bypass mode, i.e. when the control signal BP is in H level, the NOR circuit NOR1 outputs an output in L level, irrespective of the inputted signal. Further, when the control signal BP is in H level (the inverted control signal /BP is in L level), the clocked NAND circuit NAND2 outputs an output in H level, irrespective of the inputted signal.

The output of the NOR circuit NOR1 is fetched by the transmission gate G3 when the clock CP turns to be in H level, and shifts the node P to be in L level. The level of the node P is inverted through the inverter INV2 and the buffer circuit 13 and outputted as the data output Q. That is, when the clock CP turns to be in H level, the data output Q turns to be in H level.

On the other hand, when the clock CP turns to be in L level, the node P shifts to be in H level by the output of the clocked NAND circuit NAND2. The level of the node P is inverted through the inverter INV2 and the buffer circuit 13 and outputted as the data output Q. That is, when the clock CP turns to be in L level, the data output Q turns to be in L level.

In the above manner, when the control signal BP is in H level, the clock CP is outputted as it is with the same logic as the data output Q, and the configuration is equivalent to a configuration that the clock CK from the PLL circuit 2 is outputted in a bypassing manner.

Further, a transmission path of the clock from the node P to the output terminal of the data output Q is common in the frequency division mode (non-bypass mode) and in the bypass mode. Furthermore, when the clock CP rises from the L level to the H level, a delay time in a case where the output of the NOR circuit NOR1 is transmitted by the transmission gate G3 and shifts the node P in the frequency division mode and a delay time in a case where the level change of the clock CP appears at the node P through the transmission gate G3 in the bypass mode are equal to each other, and a difference of latencies in the respective modes is not caused.

Furthermore, when the clock CP falls from the H level to the L level, a difference of latencies in the frequency division mode and in the bypass mode is a difference between a delay time by the transmission gate G3 and a delay time by the clocked NAND circuit NAND2, and is extremely small.

Thus, in the present embodiment also, the same truth table as shown in FIG. 5 is obtained and the same effects as those of the first embodiment can be obtained.

### Third Embodiment

FIG. 12 is a circuit diagram showing a third embodiment of the present invention. In FIG. 12, the same reference signs are assigned to the same elements in FIG. 11 and the description thereof is omitted.

In a D-type flip-flop 45 of the present embodiment, the master latch 111 has the same configuration as in the first embodiment. A slave latch 143 and a buffer circuit 113 of the D-type flip-flop 45 are different from the slave latch 43 and the buffer circuit 13 in FIG. 11, respectively, in that a clocked NOR circuit NOR2 is adopted in place of the clocked NAND circuit NAND2, and the inverter INV4 is omitted.

In FIG. 12, the data input D supplied to the D-type flip-flop 45 is given to the inverter ING1 in the master latch 111. The inverter ING1 fetches the data input D into the master latch 111 and gives the data input to one input terminal of the NAND circuit NAND1 under control of the clock CP and the inverted clock /CP thereof which are supplied to a control terminal. The inverted control signal /BP is supplied to the other input terminal of the NAND circuit NAND1.

An output of the NAND circuit NAND1 is supplied to the inverter ING2. The inverter ING2 inverts the output of the NAND circuit NAND1 and outputs the inverted output to the one input terminal of the NAND circuit NAND1 under control of the inverted clock /CP and the clock CP which are inputted to a control terminal. That is, a latch circuit is constituted by the NAND circuit NAND1 and the inverter ING2, and the latch circuit outputs and holds the non-inverting signal of the data input D in the H level period of the clock CP.

The output of the NAND circuit NAND1 is supplied to the transmission gate G3. The transmission gate G3 fetches the output of the NAND circuit NAND1 into the slave latch 143 under control of the inverted clock /CP and the clock CP which are inputted to a control terminal. For example, the transmission gate G3 outputs the inputted signal in H level of the clock CP.

The inverter INV2 inverts the input signal and gives the inverted input signal to one input terminal of the clocked NOR circuit NOR2. The control signal BP is given to the other input terminal of the clocked NOR circuit NOR2. The clocked NOR circuit NOR2 gives the inputted signal to the inverter INV2 under control of the clock CP and the inverted clock /CP which are supplied to a control terminal. That is, the inverter INV2 and the clocked NOR circuit NOR2 function as a latch circuit, and the latch circuit outputs the inverted signal of the data input D to the buffer circuit 113 and holds the signal in the L level period of the clock CP. The buffer circuit 113 inverts the output of the inverter INV2 and outputs the inverted output as the data output Q.

The other configurations are the same as those of the first and second embodiments.

Next, an operation of the thus configured embodiment will be described.

When the control signal BP is in L level and the inverted control signal /BP is in H level, i.e. in the frequency division mode (non-bypass mode), the NAND circuit NAND1 functions as an inverter and the clocked NOR circuit NOR2 functions as a clocked inverter. Therefore, in this case, the NAND circuit NAND1 exhibits the same operation as the inverter INV1 in FIG. 7. Further, the clocked NOR circuit NOR2 exhibits the same operation as the inverter ING4 in FIG. 7.

Therefore, when the control signal BP is in L level, the latch circuit in the master latch 111 outputs and holds the non-inverting signal of the data input D, and the latch circuit in the slave latch 143 inverts the output of the master latch 111 and holds the inverted output. That is, the latch circuit in the slave latch 143 outputs the inverted signal of the data input D to the buffer circuit 113 and holds the inverted signal. The buffer circuit 113 inverts the inverted signal of the slave latch 143 and outputs the signal. That is, in this case, the D-type flip-flop 45 of FIG. 12 performs an operation of an ordinary D-type flip-flop.

In the bypass mode, i.e. when the control signal BP is in H level (the inverted control signal /BP is in L level), the NAND circuit NAND1 outputs an output in H level irrespective of the inputted signal. Further, when the control signal BP is in H level (the inverted control signal /BP is in L level), the clocked NOR circuit NOR2 outputs an output in L level, irrespective of the inputted signal.

The output of the NAND circuit NAND1 is fetched by the transmission gate G3 when the clock CP turns to be in H level and shifts the node P to be in H level. The level of the node P is outputted through the inverter INV2 and the buffer circuit 113 as the data output Q. That is, when the clock CP turns to be in H level, the data output Q turns to be in H level.

On the other hand, when the clock CP turns to be in L level, the node P shifts to be in L level by the output of the clocked NOR circuit NOR2. The level of the node P is outputted through the inverter INV2 and the buffer circuit 113 as the data output Q. That is, when the clock CP turns to be in L level, the data output Q turns to be in L level.

In this manner, when the control signal BP is in H level, the clock CP is outputted as it is with the same logic as the data output Q, and the configuration is equivalent to a configuration that the clock CK from the PLL circuit 2 is outputted in a bypassing manner.

Further, a transmission path of the clock from the node P to the output terminal of the data output Q is common in the frequency division mode (non-bypass mode) and in the bypass mode. Furthermore, when the clock CP rises from the L level to the H level, a delay time in a case where the output of the NAND circuit NAND1 is transmitted by the transmission gate G3 and shifts the node P in the frequency division mode and a delay time in a case where the level change of the clock CP appears at the node P through the transmission gate G3 are equal to each other, and a difference of latencies in the respective modes is not caused.

Furthermore, when the clock CP falls from the H level to the L level, a difference of latencies in the frequency division mode and in the bypass mode is the difference between the delay time by the transmission gate G3 and the delay time by the clocked NOR circuit NOR2, and is extremely small.

Thus, in the present embodiment also, the same truth table as shown in FIG. 5 is obtained and the same effects as those of the first embodiment can be obtained.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A D-type flip-flop in which a data input is inputted into a master latch having a first latch circuit and a data output is outputted from a slave latch having a second latch circuit, the D-type flip-flop comprising:
a transmission element configured in the slave latch, the transmission element fetching an output of the first latch circuit and outputting the fetched output to a first node, based on a clock signal;
a first latch circuit constituting element configured in the first latch circuit, the first latch circuit constituting element functioning as an element that constitutes the first latch circuit in a first mode and outputting an output for giving one logical value to the first node through the transmission element with the output fixed in a second mode, under control of a control signal; and
a second latch circuit constituting element configured in the second latch circuit that holds a signal which appears at the first node, the second latch circuit constituting element functioning as an element that constitutes the second latch circuit in the first mode and outputting an output of other logical value to the first node based on the clock signal with the output fixed in the second mode, under control of the control signal.

2. The D-type flip-flop according to claim 1, wherein the transmission element is constituted by a clocked inverter, and the first and second latch circuit constituting elements output the same logical value in the second mode.

3. The D-type flip-flop according to claim 1, wherein the transmission element is constituted by a transmission gate, and the first and second latch circuit constituting elements output logical values different from each other in the second mode.

4. The D-type flip-flop according to claim 1, wherein the first latch circuit constituting element functions as an inverter or as a logic circuit that outputs a fixed logical value, in accordance with the control signal, and
the second latch circuit constituting element functions as a clocked inverter or as a clocked logic circuit that outputs a fixed logical value, in accordance with the control signal.

5. The D-type flip-flop according to claim 2, wherein the first latch circuit constituting element functions as an inverter or as a logic circuit that outputs a fixed logical value, in accordance with the control signal, and
the second latch circuit constituting element functions as a clocked inverter or as a clocked logic circuit that outputs a fixed logical value, in accordance with the control signal.

6. The D-type flip-flop according to claim 3, wherein the first latch circuit constituting element functions as an inverter or as a logic circuit that outputs a fixed logical value, in accordance with the control signal, and
the second latch circuit constituting element functions as a clocked inverter or as a clocked logic circuit that outputs a fixed logical value, in accordance with the control signal.

7. The D-type flip-flop according to claim 1, wherein the first latch circuit is constituted by a loop circuit including a NAND circuit to which an input signal and the control signal are inputted and a first clocked inverter that inverts an output of the NAND circuit and gives the inverted output to the NAND circuit, and
the second latch circuit is constituted by a loop circuit including a second inverter that inverts a signal which appears at the first node and a clocked NAND circuit to which an output of the second inverter and the control signal are inputted and that outputs an output to the first node at timing of the clock signal.

8. The D-type flip-flop according to claim 7, further comprising:
a second clocked inverter configured in the master latch, the second clocked inverter inverting the data input based on the clock signal and giving the inverted data input to the NAND circuit as the input signal; and
a buffer to which an output of the second inverter is given and that outputs the data output,
wherein the transmission element is a third clocked inverter that inverts the output of the NAND circuit based on the clock signal and gives the inverted output to the second inverter.

9. The D-type flip-flop according to claim 1, wherein the first latch circuit is constituted by a loop circuit including a NOR circuit to which an input signal and the control signal are inputted and a first inverter that inverts an output of the NOR circuit and gives the inverted output to the NOR circuit, and
the second latch circuit is constituted by a loop circuit including a second inverter that inverts a signal which appears at the first node and a clocked NAND circuit to which an output of the second inverter and the control signal are inputted and that outputs an output to the first node at timing of the clock signal.

10. The D-type flip-flop according to claim 9, further comprising:
a first transmission gate constituting the master latch, the first transmission gate giving the data input to the NOR circuit as the input signal based on the clock signal; and
a buffer to which an output of the second inverter is given and that outputs the data output,
wherein the transmission element is a second transmission gate that gives an output of the NOR circuit to the second inverter based on the clock signal.

11. The D-type flip-flop according to claim 1, wherein the first latch circuit is constituted by a loop circuit including a NAND circuit to which an input signal and the control signal are inputted and a first inverter that inverts an output of the NAND circuit and gives the inverted output to the NAND circuit, and
the second latch circuit is constituted by a loop circuit including a second inverter that inverts a signal which appears at the first node and a clocked NOR circuit to which an output of the second inverter and the control signal are inputted and that outputs an output to the first node at timing of the clock signal.

12. The D-type flip-flop according to claim 11, further comprising:
a third inverter configured in the master latch, the third inverter inverting the data input based on the clock signal and giving the inverted data input to the NAND circuit as the input signal; and
a fourth inverter to which an output of the second inverter is given and that inverts the output of the second inverter and outputs the inverted output of the second inverter,
wherein the transmission element is a first transmission gate that gives an output of the NOR circuit to the second inverter based on the clock signal.

13. The D-type flip-flop according to claim 1, wherein in the first mode, the transmission element fetches an output of the first latch circuit in synchronism with timing of rising or falling of the clock signal and outputs the fetched output to the first node, and the second latch circuit constituting element gives an output of the other logical value to the first node in synchronism with timing of rising or falling of the clock signal.

14. The D-type flip-flop according to claim 1, wherein a logical value of the data output outputted from the slave latch is based on the logical value of the first node in the first mode and the second mode.

15. A clock generating circuit comprising:
a clock pulse generating circuit that generates a clock signal;
a frequency dividing circuit that divides a frequency of the clock signal generated by the clock pulse generating circuit; and
the D-type flip-flop according to claim 1,
wherein the D-type flip-flop is capable of outputting an output of the frequency dividing circuit.
